(19) United States
(12) Patent Application Publication
(10) Pub. No.: US 2026/0344542 A1
(43) Pub. Date: Oct. 29, 2026

(54) SEMICONDUCTOR DEVICE AND SEMICONDUCTOR APPARATUS

(71) Applicant: Fujitsu Limited, Kawasaki-shi (JP)

(72) Inventor: Yuichi MINOURA, Machida (JP)

(73) Assignee: Fujitsu Limited, Kawasaki-shi (JP)

(21) Appl. No.: 19/572,720

(22) Filed: Mar. 19, 2026

(30) Foreign Application Priority Data
Apr. 23, 2025 (JP) 2025-071430

(51) Int. Cl. H10W 90/00; H10D 30/47; H10D 80/20; H10W 20/41; H10W 20/42; H10W 20/44; H10W 72/30; H10D 62/824; H10W 72/00

(52) U.S. Cl. CPC H10W 90/734; H10D 30/471; H10D 80/251; H10W 20/422; H10W 20/435; H10W 20/4432; H10W 72/3524; H10D 62/824; H10W 72/07336; H10W 72/07341

(57) ABSTRACT

A semiconductor device includes a substrate having a first surface, a second surface, and a side surface connecting the first surface and the second surface, a semiconductor element provided on the first surface, a metal layer provided on the first surface and electrically connected to the semiconductor element, a via wiring provided on an inner surface of a through hole and connected to the metal layer, the through hole penetrating from the first surface to the second surface and overlapping the metal layer in plan view, and a pad provided on the second surface and connected to the via wiring, wherein the substrate includes a groove provided in the second surface from the through hole to the side surface.

### CROSS-REFERENCE TO RELATED APPLICATION

This application is based upon and claims the benefit of priority of Japanese Patent Application No. 2025-071430 filed on Apr. 23, 2025, the entire contents of which are incorporated herein by reference.

### FIELD

A certain aspect of the present embodiments relates to a semiconductor device and a semiconductor apparatus.

### BACKGROUND

A semiconductor device is known which has a configuration in which a semiconductor element on a substrate and a lower surface of the substrate are electrically connected to each other through a via wiring provided in a through hole penetrating the substrate (for example, U.S. Patent No. 8,718,720, Japanese Patent Application Publication No. 2016-1686, U.S. Patent Application Publication No. 2019/0096755, and Japanese Patent Application Publication No. 2019-145546). In addition, it is known that, when a semiconductor device is mounted on a mounting substrate with a solder material, a groove is formed in a pad provided on a lower surface of the substrate in order to discharge air in a through hole to the outside (for example, U.S. Patent No. 8,718,720). It is also known that a hole is provided between a metal layer provided on the upper surface of the substrate so as to cover the through hole and the upper surface of the substrate, thereby discharging the air in the through hole to the outside (for example, Japanese Patent Application Publication No. 2016-1686).

### SUMMARY

According to an aspect of the present disclosure, there is provided a semiconductor device including: a substrate having a first surface, a second surface, and a side surface connecting the first surface and the second surface; a semiconductor element provided on the first surface; a metal layer provided on the first surface and electrically connected to the semiconductor element; a via wiring provided on an inner surface of a through hole and connected to the metal layer, the through hole penetrating from the first surface to the second surface and overlapping the metal layer in plan view; and a pad provided on the second surface and connected to the via wiring, wherein the substrate includes a groove provided in the second surface from the through hole to the side surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1A is a cross-sectional view of a semiconductor device according to a first embodiment.

FIG. 1B is a plan view of a lower surface of a substrate in the first embodiment.

FIG. 1C is a plan view of a through hole and a metal layer in the first embodiment.

FIGS. 2A-2C are cross-sectional views illustrating a method of manufacturing a semiconductor device according to the first embodiment (Part 1).

FIGS. 3A-3C are cross-sectional views illustrating a method of manufacturing a semiconductor device according to the first embodiment (Part 2).

FIGS. 4A-4C are cross-sectional views illustrating a method of manufacturing a semiconductor device according to the first embodiment (Part 3).

FIG. 5 is a cross-sectional view of a semiconductor device according to a comparative example.

FIGS. 6A and 6B are cross-sectional views illustrating a step of mounting a semiconductor device according to a comparative example on a mounting substrate to form a semiconductor apparatus.

FIGS. 7A and 7B are cross-sectional views illustrating a step of mounting the semiconductor device according to the first embodiment on a mounting substrate to form a semiconductor apparatus.

FIG. 8A is a cross-sectional view of a semiconductor device according to a second embodiment.

FIG. 8B is a cross-sectional view of a groove in the second embodiment.

FIGS. 9A-9C are cross-sectional views illustrating a method of manufacturing a semiconductor device according to the second embodiment (Part 1).

FIGS. 10A-10C are cross-sectional views illustrating a method of manufacturing a semiconductor device according to the second embodiment (Part 2).

FIGS. 11A and 11B are cross-sectional views illustrating a step of mounting the semiconductor device according to the second embodiment on a mounting substrate to form a semiconductor apparatus.

FIG. 12A is a cross-sectional view of a semiconductor device according to a third embodiment.

FIG. 12B is a cross-sectional view of a groove in the third embodiment.

FIGS. 13A-13C are cross-sectional views illustrating a method of manufacturing a semiconductor device according to the third embodiment.

FIGS. 14A and 14B are cross-sectional views illustrating a step of mounting the semiconductor device according to the third embodiment on a mounting substrate to form a semiconductor apparatus.

### DESCRIPTION OF EMBODIMENTS

When the semiconductor device is mounted on the mounting substrate with the solder material, if air is trapped in the through hole, the metal layer provided to cover the through hole may be damaged. In order to discharge the air in the through hole, when a hole is provided between a metal layer covering the through hole on the substrate and the substrate as described in, for example, Japanese Patent Application Publication No. 2016-1686, a processing process is performed on the substrate, and thus characteristics of the semiconductor element on the substrate may deteriorate. In addition, for example, as in U.S. Patent No. 8,718,720, in a configuration in which air in the through hole is discharged by forming a groove in a pad provided on the lower surface of the substrate, the groove is blocked by the solder material, and thus the air may not be sufficiently discharged.

In one aspect, an object is to provide a configuration capable of discharging air in a through hole.

Hereinafter, embodiments of the present invention will be described with reference to the drawings.

### First Embodiment

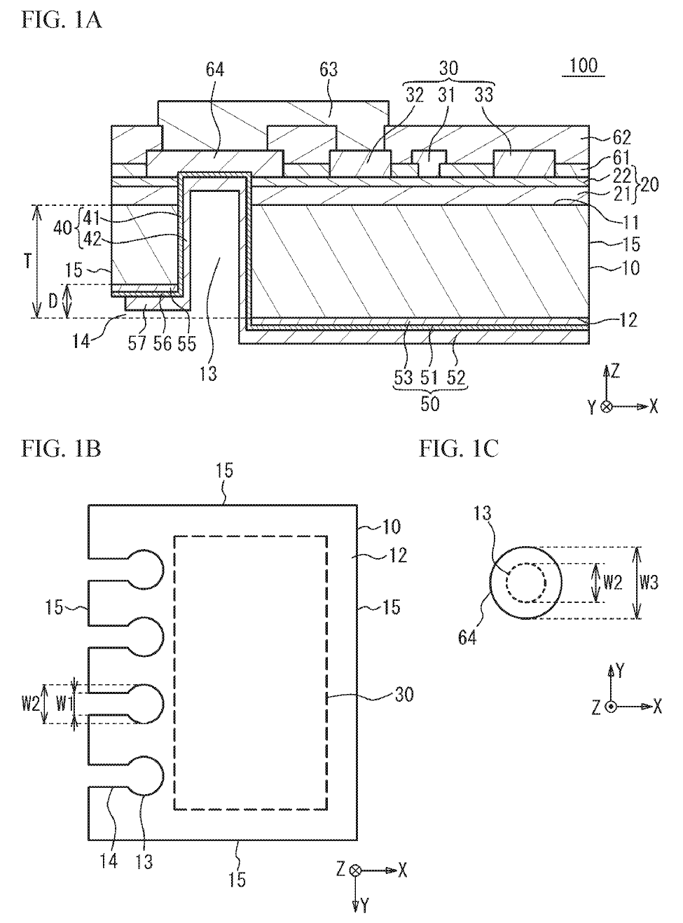

FIG. 1A is a cross-sectional view of a semiconductor device 100 according to a first embodiment, FIG. 1B is a plan view of a lower surface 12 of a substrate 10 in the first embodiment, and FIG. 1C is a plan view of a through hole 13 and a metal layer 64 in the first embodiment. FIG. 1B mainly illustrates the through holes 13, grooves 14, and a semiconductor element 30. As illustrated in FIG. 1A, a nitride semiconductor layer 20 is provided on an upper surface 11 of the substrate 10. The substrate 10 is, for example, a silicon carbide (SiC) substrate. The thickness T of the substrate 10 is, for example, 50μm to 150μm. The substrate 10 is not limited to the SiC substrate, and may be a sapphire substrate, a silicon substrate, or the like.

The nitride semiconductor layer 20 includes a channel layer 21 and an electron supply layer 22 provided on the channel layer 21. The channel layer 21 is, for example, a gallium nitride (GaN) layer. The electron supply layer 22 is, for example, an aluminum gallium nitride (AlGaN) layer. The nitride semiconductor layer 20 may include a buffer layer between the substrate 10 and the channel layer 21. The channel layer 21 and the electron supply layer 22 may be formed of a nitride semiconductor other than GaN or AlGaN. Examples of the nitride semiconductor include GaN, InN, AlN, AlGaN, InGaN, and AlInGaN.

The semiconductor element 30 is provided on the upper surface 11 of the substrate 10. The semiconductor element 30 is a field effect transistor such as a high electron mobility transistor including a gate electrode 31, and a source electrode 32 and a drain electrode 33 arranged with the gate electrode 31 interposed therebetween. The gate electrode 31, the source electrode 32, and the drain electrode 33 are each provided in a plurality to form a finger structure.

The gate electrode 31, the source electrode 32, and the drain electrode 33 are provided in contact with the electron supply layer 22. The source electrode 32 and the drain electrode 33 are in ohmic contact with the electron supply layer 22. The gate electrode 31 is a stacked film of a nickel (Ni) layer and a gold (Au) layer, for example. The source electrode 32 and the drain electrode 33 are, for example, a stacked film of a titanium (Ti) layer and an aluminum (Al) layer.

The metal layer 64 is provided on the electron supply layer 22. The thickness of the metal layer 64 is, for example, from the 100nm to the 500nm. The metal layer 64 is a stacked film of a nickel (Ni) layer and a gold (Au) layer, for example. An insulating film 61 and an insulating film 62 are provided on the electron supply layer 22 so as to cover the gate electrode 31, the source electrode 32, the drain electrode 33, and the metal layer 64. The insulating film 61 and the insulating film 62 are, for example, silicon nitride (SiN) films.

A wiring 63 electrically connecting the metal layer 64 and the source electrode 32 is provided so as to fill openings formed in the insulating film 62. The wiring 63 includes, for example, a gold (Au) layer. The thickness of the wiring 63 is several micrometers (for example, 1μm to 5μm).

The through hole 13 penetrating the substrate 10 from the upper surface 11 to the lower surface 12 is provided below the metal layer 64. The through hole 13 also penetrates the nitride semiconductor layer 20. As illustrated in FIG. 1C, in a plan view (when viewed from the Z direction), the metal layer 64 is larger than the through hole 13 and completely covers the through hole 13. Therefore, a maximum thickness W3 of the metal layer 64 is larger than a maximum thickness W2 of the through hole 13. The maximum W2 of the through hole 13 is, for example, 50μm to 150μm. The maximum thickness W3 of the metal layer 64 is, for example, 1.2 to 1.5 times the maximum thickness W2.

A via wiring 40 is provided on the inner surface of the through hole 13. The via wiring 40 includes, for example, a seed layer 41 and a plating layer 42. The seed layer 41 is a stacked film of a titanium (Ti) layer and a gold (Au) layer, for example. The plating layer 42 is, for example, a gold (Au) plating layer. The via wiring 40 is in contact with the lower surface of the metal layer 64. Therefore, the via wiring 40 is electrically connected to the source electrode 32 through the metal layer 64 and the wiring 63.

As illustrated in FIGS. 1A and 1B, the groove 14 is provided in the lower surface 12 of the substrate 10. The groove 14 is a recess provided in the lower surface 12 of the substrate 10 and has one end connected to the through hole 13 and the other end connected to a side surface 15 connecting the upper surface 11 and the lower surface 12 of the substrate 10. When the plurality of through holes 13 are provided, different grooves 14 are connected to the plurality of through holes 13, respectively. In plan view, the groove 14 is located on the opposite side of the through hole 13 from the region where the semiconductor element 30 is provided (the region where the gate electrode 31, the source electrode 32, and the drain electrode 33 are provided). A depth D of the groove 14 is, for example, 1/20 or more and 1/4 or less of a thickness T of the substrate 10. In plan view, a maximum width W1 of the groove 14 is smaller than a maximum width W2 of the through hole 13. For example, the maximum width W1 is 0.3 times or more and 0.9 times or less the maximum width W2.

As illustrated in FIG. 1A, a pad 50 connected to the via wiring 40 is provided on the lower surface 12 of the substrate 10. Therefore, the pad 50 is electrically connected to the source electrode 32 through the via wiring 40, the metal layer 64, and the wiring 63. The source electrode 32 is connected to the pad 50 through the via wiring 40 and the like, and thereby, the inductance between the source electrode 32 and the ground can be reduced. The pad 50 includes a metal layer 53, a seed layer 51, and a plating layer 52. The metal layer 53 is, for example, a nickel (Ni) layer. The seed layer 51 is connected to the seed layer 41 and is formed of the same material as the seed layer 41. The seed layer 51 is a stacked film of a Ti layer and an Au layer, for example. The plating layer 52 is connected to the plating layer 42 and is formed of the same material as the plating layer 42. The plating layer 42 is, for example, an Au plating layer. The metal layer 53 may not be provided.

A metal layer 55, a seed layer 56, and a plating layer 57 are provided on the inner surface of the groove 14 provided on the lower surface 12 of the substrate 10. The metal layer 55 is formed of the same material as the metal layer 53. The metal layer 55 is, for example, a Ni layer. The seed layer 56 is connected to the seed layers 41 and 51 and is formed of the same material as the seed layers 41 and 51. The seed layer 56 is a stacked film of a Ti layer and an Au layer, for example. The plating layer 57 is connected to the plating layers 42 and 52 and is formed of the same material as the plating layers 42 and 52. The plating layer 57 is, for example, an Au plating layer. The lower surface of the plating layer 57 on the bottom surface of the groove 14 is located in a +Z direction from the lower surface of the plating layer 52 of the pad 50 by the depth D of the groove 14.

### Manufacturing Method

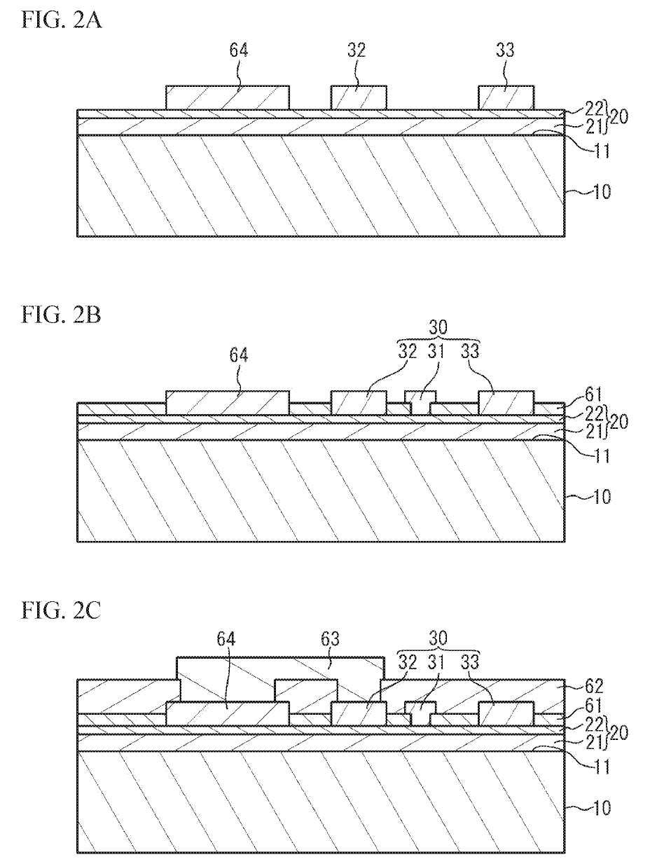

FIGS. 2A-4C are cross-sectional views illustrating a method of manufacturing the semiconductor device 100 according to the first embodiment. As illustrated in FIG. 2A, the nitride semiconductor layer 20 including the channel layer 21 and the electron supply layer 22 is formed on the upper surface 11 of the substrate 10 by, for example, a metal organic chemical vapor deposition (MOCVD) method. Next, the source electrode 32 and the drain electrode 33, which are stacked films of a Ti layer and an Al layer, are formed on the electron supply layer 22 by using, for example, a vacuum deposition method and a lift-off method. Thereafter, the source electrode 32 and the drain electrode 33 are subjected to heat treatment to be in ohmic contact with the electron supply layer 22. Next, the metal layer 64, which is a stacked film of a Ni layer and an Au layer, is formed on the electron supply layer 22 by using, for example, the vacuum deposition method and the lift-off method. The Ni layer functions as an etching stopper layer in the formation of the through hole 13 described later. The Au layer is provided for connection with the wiring 63.

As illustrated in FIG. 2B, the insulating film 61, which is a SiN film, is formed on the nitride semiconductor layer 20 by, for example, a chemical vapor deposition (CVD) method so as to cover the side surfaces of the source electrode 32, the drain electrode 33, and the metal layer 64. Next, an opening is formed in the insulating film 61, and the gate electrode 31, which is a stacked film of a Ni layer and an Au layer, is formed in the opening by using, for example, the vacuum deposition method and the lift-off method. The gate electrode 31 is formed in contact with the electron supply layer 22. Thus, the semiconductor element 30 is formed on the upper surface 11 of the substrate 10. When the metal layer 64 and the gate electrode 31 have the same layer structure, the metal layer 64 may be formed simultaneously with the gate electrode 31.

As illustrated in FIG. 2C, the insulating film 62, which is a SiN film, is formed on the insulating film 61 so as to cover the gate electrode 31, the source electrode 32, the drain electrode 33, and the metal layer 64 by using, for example, the CVD method. Next, after openings are formed in the insulating film 62, the wiring 63 that electrically connects the metal layer 64 and the source electrode 32 is formed so as to fill the openings. The wiring 63 is formed by, for example, a plating method or a sputtering method.

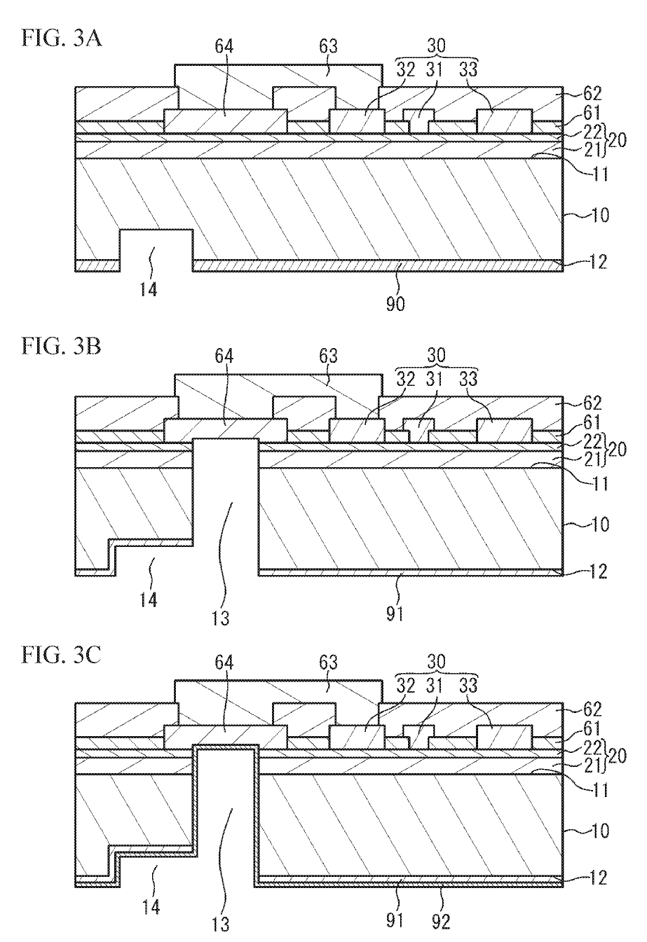

As illustrated in FIG. 3A, a photoresist film 90 having an opening in a formation region of the groove 14 is formed on the lower surface 12 of the substrate 10. Next, the substrate 10 is etched using the photoresist film 90 as a mask, thereby forming the groove 14 in the lower surface 12 of the substrate 10. When the substrate 10 is a SiC substrate, the grooves 14 are formed by etching the substrate 10 by a dry etching method using a fluorine-based gas such as SF₆ gas or a chlorine-based gas such as Cl₂ gas as an etching gas, for example.

As illustrated in FIG. 3B, after the photoresist film 90 is removed, a metal mask layer 91 having an opening in a formation region of the through hole 13 is formed on the lower surface 12 of the substrate 10 and the inner surface of the groove 14. The metal mask layer 91 is, for example, a Ni layer formed by the plating method, and has a thickness of 1μm or more. Next, the substrate 10 is etched using the metal mask layer 91 as a mask, thereby forming the through hole 13 that overlaps the metal layer 64 in plan view, penetrates the substrate 10 from the lower surface 12 to the upper surface 11, and penetrates the nitride semiconductor layer 20. One end of the groove 14 is connected to the through hole 13. When the substrate 10 is a SiC substrate, the through holes 13 are formed by etching the substrate 10 by a dry etching method using a mixture gas of SF₆ gas and O₂ gas as an etching gas, for example. Since the metal mask layer 91 of the Ni layer has high resistance to dry etching using a fluorine-based gas, the metal mask layer 91 can be used as an etching mask. Further, since the metal layer 64 includes the Ni layer, the metal layer 64 can be used as an etching stopper layer in the dry etching of the substrate 10 using the fluorine-based gas.

As illustrated in FIG. 3C, a seed layer 92, which is a stacked film of a Ti layer and an Au layer, is formed on the lower surface 12 of the substrate 10, the inner surface of the through hole 13, and the inner surface of the groove 14 by using, for example, the sputtering method.

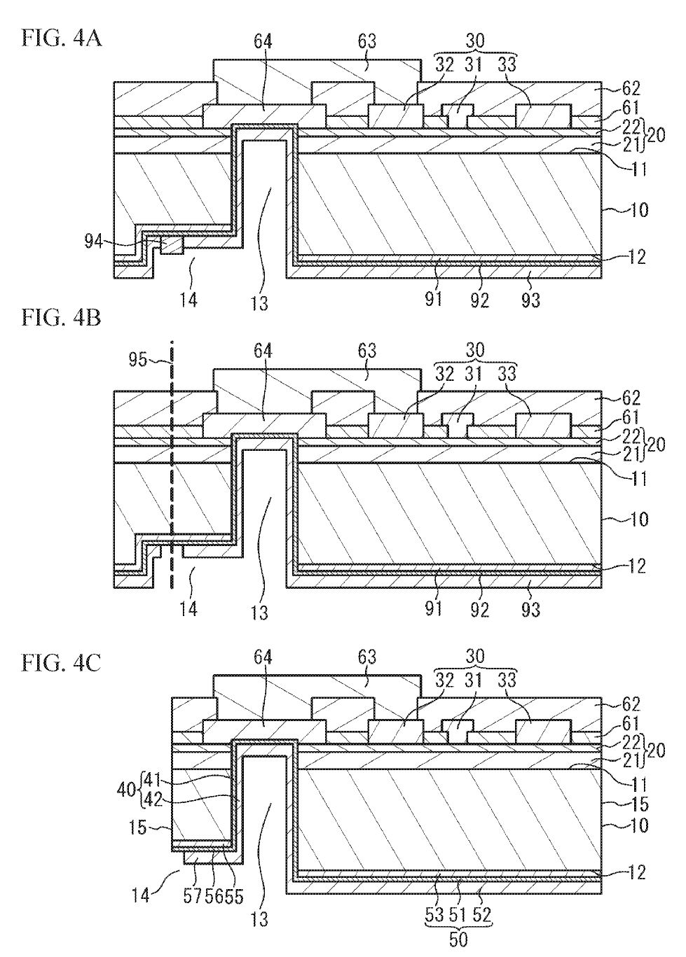

As illustrated in FIG. 4A, after a photoresist film 94 is formed in a dicing region where the semiconductor device is to be singulated, a plating layer 93 is formed by an electrolytic plating method using the photoresist film 94 as a mask.

As illustrated in FIG. 4B, after the photoresist film 94 is removed, the semiconductor device is singulated along a dicing line 95.

As illustrated in FIG. 4C, the groove 14 connecting the through hole 13 and the side surface 15 of the substrate 10 is formed in the lower surface 12 of the substrate 10 by singulating the semiconductor device. The pad 50 including the metal layer 53 formed of the metal mask layer 91, the seed layer 51 formed of the seed layer 92, and the plating layer 52 formed of the plating layer 93 is formed on the lower surface 12 of the substrate 10. The metal layer 55 formed of the metal mask layer 91, the seed layer 56 formed of the seed layer 92, and the plating layer 57 formed of the plating layer 93 are formed on the inner surface of the groove 14. The via wiring 40 including the seed layer 41 formed of the seed layer 92 and the plating layer 42 formed of the plating layer 93 is formed on the inner surface of the through hole 13. The via wiring 40 and the pad 50 are connected to each other. As described above, the semiconductor device 100 of the first embodiment is formed.

### Comparative Example

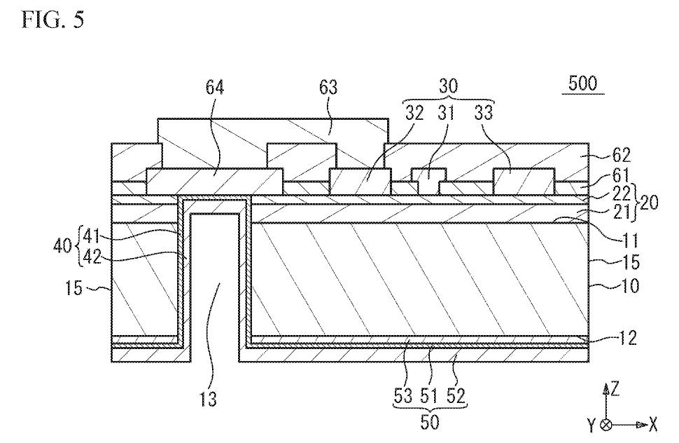

FIG. 5 is a cross-sectional view of a semiconductor device 500 according to a comparative example. As illustrated in FIG. 5, in the comparative example, the lower surface 12 of the substrate 10 is not provided with a groove having one end connected to the through hole 13 and the other end connected to the side surface 15 of the substrate 10. The other configurations of the comparative example are the same as those of the first embodiment, and thus the description thereof will be omitted.

### Semiconductor Device in Comparative Example

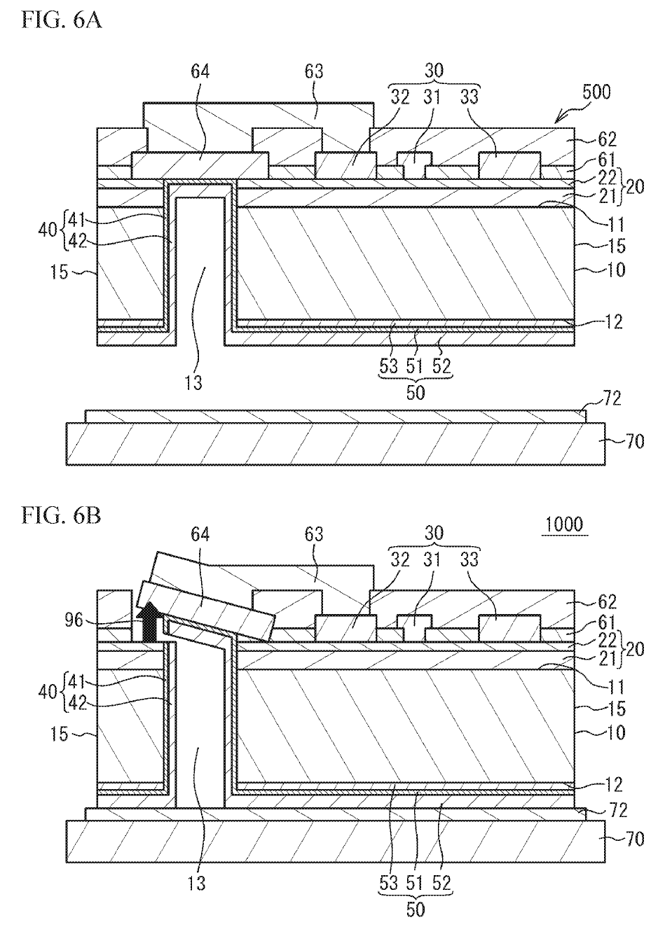

FIGS. 6A and 6B are cross-sectional views illustrating a step of forming a semiconductor apparatus 1000 by mounting the semiconductor device 500 according to a comparative example on a mounting substrate 70. As illustrated in FIG. 6A, the mounting substrate 70 having a solder material 72 formed on the upper surface thereof is prepared. As illustrated in FIG. 6B, the pad 50 provided on the lower surface 12 of the substrate 10 is disposed on the solder material 72, and the temperature of the solder material 72 is increased to an appropriate temperature, thereby bonding the pad 50 and the solder material 72. At this time, air is trapped in the through hole 13. The air trapped in the through hole 13 expands because the air is heated to a high temperature by the heating of the solder material 72. The metal layer 64 and the wiring 63 are provided on the through hole 13. Since the thickness of the metal layer 64 is several hundred nm and the thickness of the wiring 63 is several μm, the metal layer 64 and the wiring 63 are weak in strength and are easily damaged when a load is applied from the outside. When the air in the through hole 13 expands, a load 96 is applied to the metal layer 64 and the wiring 63, and thus the via wiring 40, the metal layer 64, and the wiring 63 may be damaged. This may cause an increase in electrical resistance or electrical insulation between the semiconductor element 30 and the via wiring 40.

### Semiconductor Device in First Embodiment

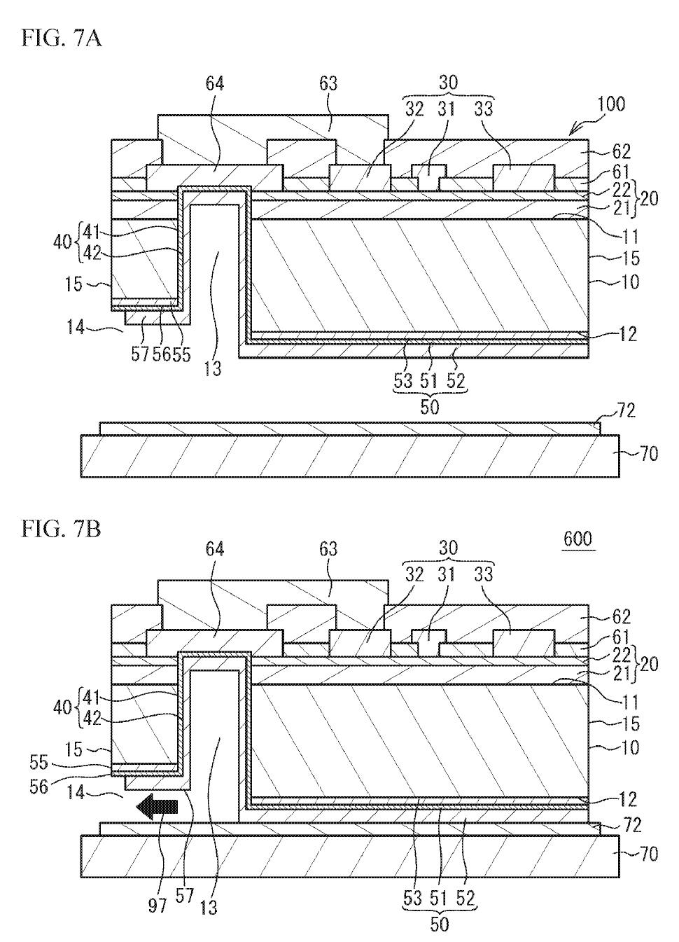

FIGS. 7A and 7B are cross-sectional views illustrating a step of mounting the semiconductor device 100 on the mounting substrate 70 to form a semiconductor apparatus 600. As illustrated in FIG. 7A, the mounting substrate 70 having the solder material 72 formed on the upper surface thereof is prepared. The solder material 72 is, for example, gold-tin solder. As illustrated in FIG. 7B, the pad 50 provided on the lower surface 12 of the substrate 10 is disposed on the solder material 72, and the temperature of the solder material 72 is increased to an appropriate temperature, thereby bonding the pad 50 and the solder material 72. Since the groove 14 is provided in the lower surface 12 of the substrate 10 from the through hole 13 to the side surface 15 of the substrate 10, a gap is formed by the groove 14 between the substrate 10 and the mounting substrate 70. Therefore, even if the air in the through hole 13 is heated to a high temperature and expanded by the heating of the solder material 72, the air is discharged to the outside through the gap formed by the groove 14 as indicated by an arrow 97. This suppresses the load applied to the via wiring 40, the metal layer 64, and the wiring 63, thereby suppressing damage to the via wiring 40, the metal layer 64, and the wiring 63.

According to the first embodiment, as illustrated in FIGS. 1A-1C, the through hole 13 is provided to penetrate the substrate 10 from the upper surface 11 (first surface) to the lower surface 12 (second surface) and overlap the metal layer 64 provided on the upper surface 11 in plan view. The via wiring 40 connected to the metal layer 64 is provided on the inner surface of the through hole 13. The groove 14 is provided in the lower surface 12 of the substrate 10 from the through hole 13 to the side surface 15 of the substrate 10. Thus, as illustrated in FIG. 7B, when the pad 50 connected to the via wiring 40 and provided on the lower surface 12 of the substrate 10 is bonded to the solder material 72 of the mounting substrate 70, the gap is formed by the groove 14 between the substrate 10 and the mounting substrate 70. This allows air in the through hole 13 to be discharged to the outside through the gap formed by the groove 14. Therefore, even when the air in the through hole 13 expands due to the temperature rise, the load applied to the via wiring 40 and the metal layer 64 can be reduced, and the occurrence of damage to the via wiring 40 and the metal layer 64 can be suppressed. Further, by forming the groove 14 in the lower surface 12 of the substrate 10, the depth D of the groove 14 can be increased as compared with the case where the groove is formed in the pad provided on the lower surface of the substrate as in U.S. Patent No. 8,718,720. Therefore, it is possible to prevent the gap formed by the groove 14 from being blocked by the solder material 72, and to more reliably discharge the air in the through hole 13 to the outside.

In the first embodiment, as illustrated in FIG. 1B, the groove 14 is provided on a side opposite to the semiconductor element 30 across the through hole 13. Accordingly, even when the groove 14 is provided in the substrate 10, it is possible to suppress the transmission of heat generated in the semiconductor element 30 to the outside via the substrate 10 from being hindered by the groove 14. Therefore, it is possible to suppress deterioration of the heat dissipation of the semiconductor device.

In the first embodiment, as illustrated in FIG. 1B, the maximum width W1 of the groove 14 is smaller than the maximum width W2 of the through hole 13 in plan view. Accordingly, even when the groove 14 is provided in the substrate 10, it is possible to suppress the transmission of heat generated in the semiconductor element 30 to the outside via the substrate 10 from being hindered by the groove 14. Therefore, it is possible to suppress deterioration of the heat dissipation of the semiconductor device. From the viewpoint of suppressing deterioration of the heat dissipation, the maximum width W1 of the groove 14 is preferably 0.9 times or less, more preferably 0.8 times or less, and still more preferably 0.7 times or less the maximum width W2 of the through hole 13. In respect of discharging the air in the through hole 13, the maximum width W1 of the groove 14 is preferably 0.3 times or more, more preferably 0.4 times or more, and still more preferably 0.5 times or more the maximum width W2 of the through hole 13.

In the first embodiment, as illustrated in FIG. 1A, the depth D of the groove 14 is 1/20 or more of the thickness T (the distance between the upper surface 11 and the lower surface 12) of the substrate 10. This can suppress the air in the through hole 13 from being less likely to be discharged to the outside. The depth D of the groove 14 is 1/4 or less of the thickness T of the substrate 10. This can suppress the groove 14 from hindering dissipation of heat generated in the semiconductor element 30. A decrease in the strength of the substrate 10 can also be suppressed. From the viewpoint of discharging the air in the through hole 13, the depth D of the groove 14 is preferably 1/18 or more, more preferably 1/15 or more, and still more preferably 1/10 or more of the thickness T of the substrate 10. From the viewpoint of the heat dissipation and the strength of the substrate 10, the depth D of the groove 14 is preferably 1/5 or less, more preferably 1/6 or less, and still more preferably 1/7 or less of the thickness T of the substrate 10.

In the first embodiment, as illustrated in FIG. 1B, the groove 14 is provided linearly between the side surface 15 of the substrate 10 and the through hole 13 in plan view. This can suppress the groove 14 from hindering dissipation of heat generated in the semiconductor element 30. A decrease in the strength of the substrate 10 can also be suppressed.

In the first embodiment, as illustrated in FIG. 1A, the semiconductor element 30 provided on the upper surface 11 of the substrate 10 includes the gate electrode 31, the source electrode 32, and the drain electrode 33. The metal layer 64 is electrically connected to the source electrode 32. This allows the source electrode 32 to be connected to the ground through the via wiring 40 and the pad 50, thereby reducing the inductance between the source electrode 32 and the ground.

### Second Embodiment

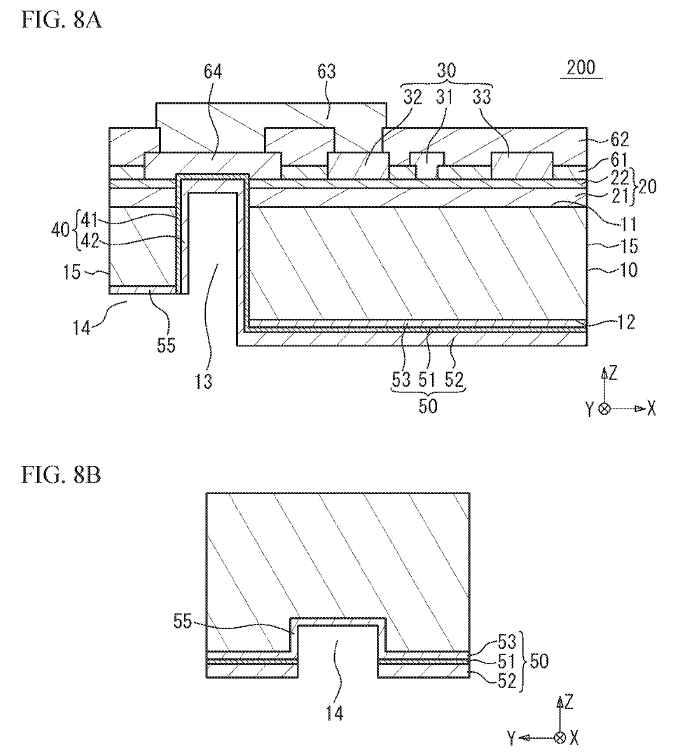

FIG. 8A is a cross-sectional view of a semiconductor device 200 according to a second embodiment, and FIG. 8B is a cross-sectional view of the groove 14 in the second embodiment. As illustrated in FIGS. 8A and 8B, in the second embodiment, only the metal layer 55, which is a Ni layer, is provided on the inner surface of the groove 14, and the seed layer 56, which is a stacked film of a Ti layer and an Au layer, and the plating layer 57, which is an Au plating layer, are not provided. The other configurations of the second embodiment are the same as those of the first embodiment, and thus the description thereof will be omitted.

### Manufacturing Method

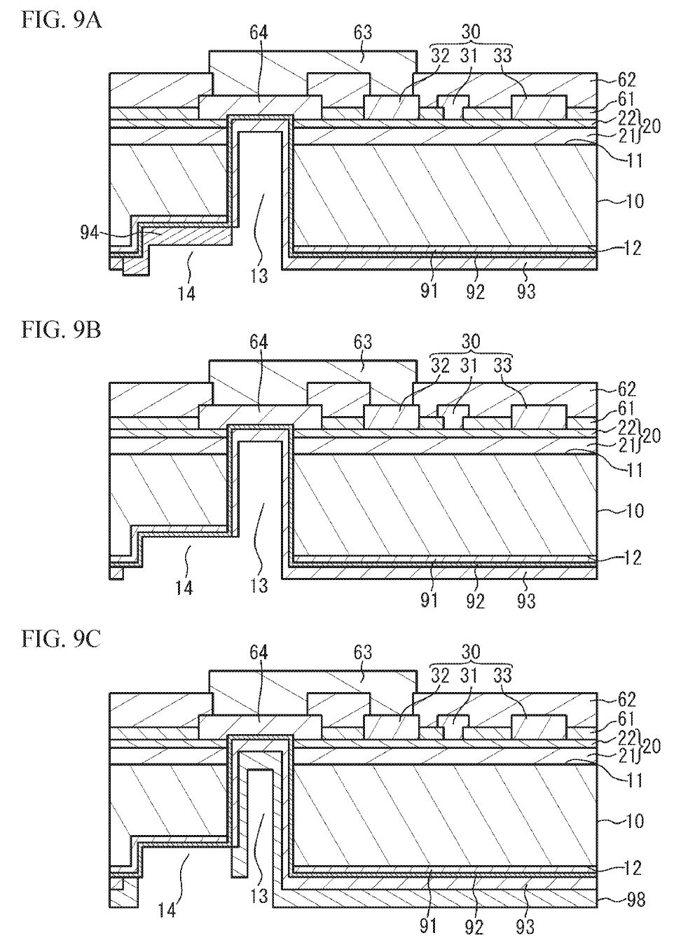

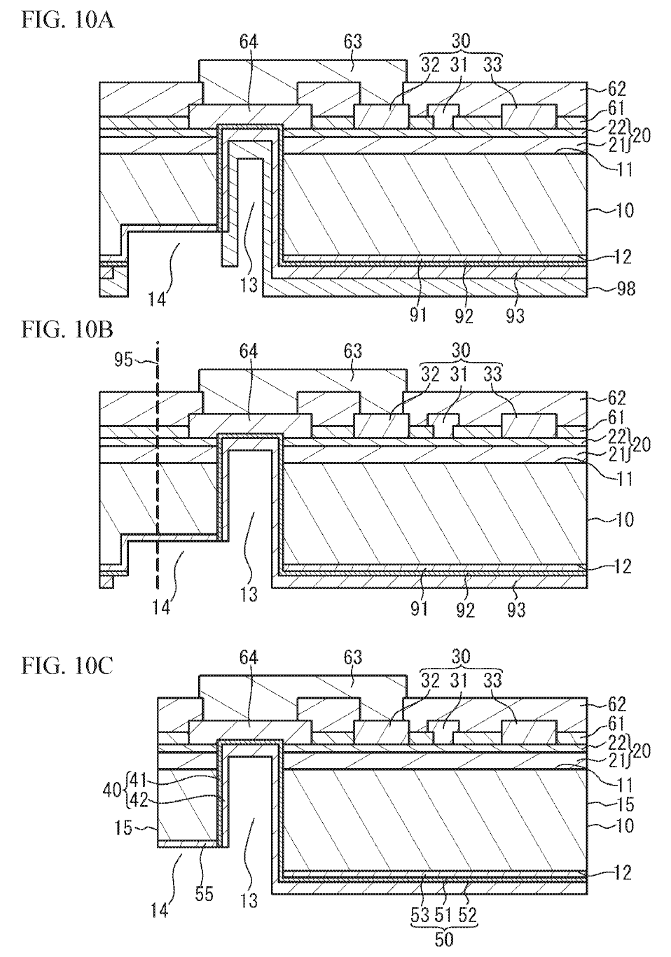

FIGS. 9A-10C are cross-sectional views illustrating a method of manufacturing the semiconductor device 200 according to the second embodiment. First, the steps illustrated in FIGS. 2A-3C of the first embodiment are performed. Next, as illustrated in FIG. 9A, the photoresist film 94 is formed so as to cover the inner surface of the groove 14, and then the plating layer 93 is formed by an electrolytic plating method using the photoresist film 94 as a mask.

As illustrated in FIG. 9B, the photoresist film 94 is removed. Since the photoresist film 94 is formed, the plating layer 93 is not formed on the inner surface of the groove 14.

As illustrated in FIG. 9C, a photoresist film 98 having an opening through which the seed layer 92 provided on the inner surface of the groove 14 is exposed is formed on the lower surface 12 of the substrate 10 and the inner surface of the through hole 13. The photoresist film 98 is formed by, for example, a spray coating method.

As illustrated in FIG. 10A, the seed layer 92 formed on the inner surface of the groove 14 is etched using the photoresist film 98 as a mask. The seed layer 92 is etched by, for example, a wet etching method. As a result, the seed layer 92 formed on the inner surface of the groove 14 is removed.

As illustrated in FIG. 10B, after the photoresist film 98 is removed, the semiconductor device is singulated along the dicing line 95.

As illustrated in FIG. 10C, the groove 14 connecting the through hole 13 and the side surface 15 of the substrate 10 is formed in the lower surface 12 of the substrate 10 by singulating the semiconductor device. The pad 50 including the metal layer 53 formed of the metal mask layer 91, the seed layer 51 formed of the seed layer 92, and the plating layer 52 formed of the plating layer 93 is formed on the lower surface 12 of the substrate 10. The metal layer 55 formed of the metal mask layer 91 is formed on the inner surface of the groove 14, and the seed layer and the plating layer are not formed. The via wiring 40 including the seed layer 41 formed of the seed layer 92 and the plating layer 42 formed of the plating layer 93 is formed on the inner surface of the through hole 13. The via wiring 40 and the pad 50 are connected to each other. As described above, the semiconductor device 200 of the second embodiment is formed.

### Semiconductor Device in Second Embodiment

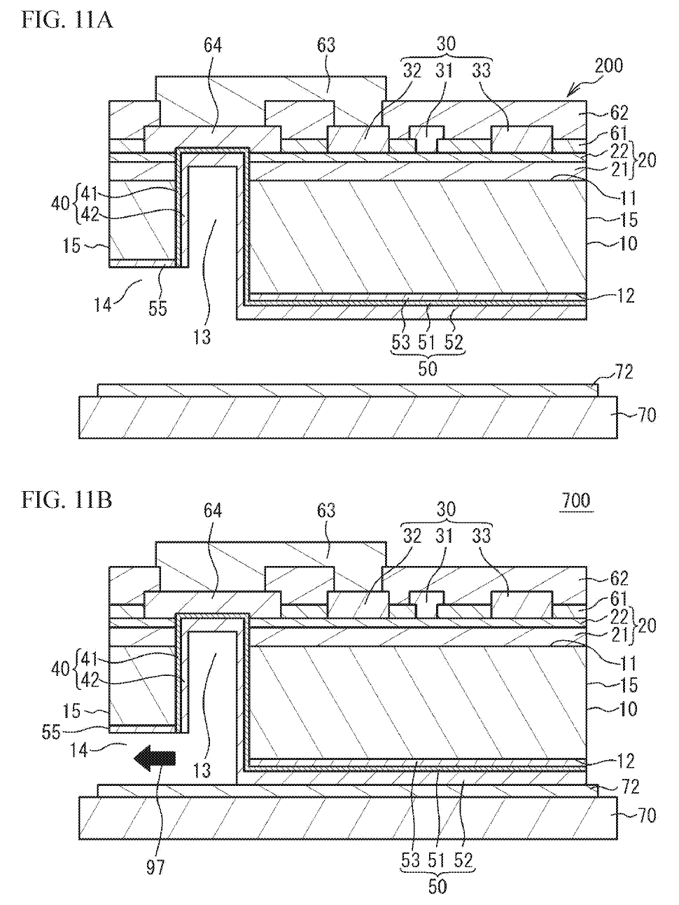

FIGS. 11A and 11B are cross-sectional views illustrating a process of mounting the semiconductor device 200 on the mounting substrate 70 to form a semiconductor apparatus 700 according to the second embodiment. As illustrated in FIGS. 11A and 11B, the pad 50 provided on the lower surface 12 of the substrate 10 is disposed on the solder material 72 provided on the mounting substrate 70, and the temperature of the solder material 72 is increased to an appropriate temperature, thereby bonding the pad 50 and the solder material 72. At this time, as in the first embodiment, since the groove 14 is provided in the lower surface 12 of the substrate 10 from the through hole 13 to the side surface 15 of the substrate 10, the air in the through hole 13 is discharged to the outside through the gap formed by the groove 14 as indicated by the arrow 97. In addition, since the seed layer 51 and the plating layer 52 containing Au are not provided on the inner surface of the groove 14, the solder material 72 made of gold-tin solder is suppressed from entering the groove 14. That is, the gap between the substrate 10 and the mounting substrate 70 is suppressed from being blocked by the solder material 72. Therefore, a path for discharging the air in the through hole 13 to the outside can be more reliably secured, and the air in the through hole 13 can be more reliably discharged to the outside.

According to the second embodiment, as illustrated in FIGS. 8A and 8B, the seed layer 56 and the plating layer 57 containing gold are not provided on the inner surface of the groove 14. When the solder material 72 contains gold (for example, in the case of gold-tin solder), the plating layer 52, which is a layer containing gold, may be used for the pad 50. In this case, when the seed layer 56 and the plating layer 57 containing gold are provided on the inner surface of the groove 14, the solder material 72 may enter the groove 14 and block the groove 14. However, as in the second embodiment, by adopting a configuration in which the seed layer 56 and the plating layer 57 containing gold are not provided on the inner surface of the groove 14, it is possible to suppress the solder material 72 from blocking the groove 14, and it is possible to suppress the air in the through hole 13 from being less likely to be discharged to the outside.

### Third Embodiment

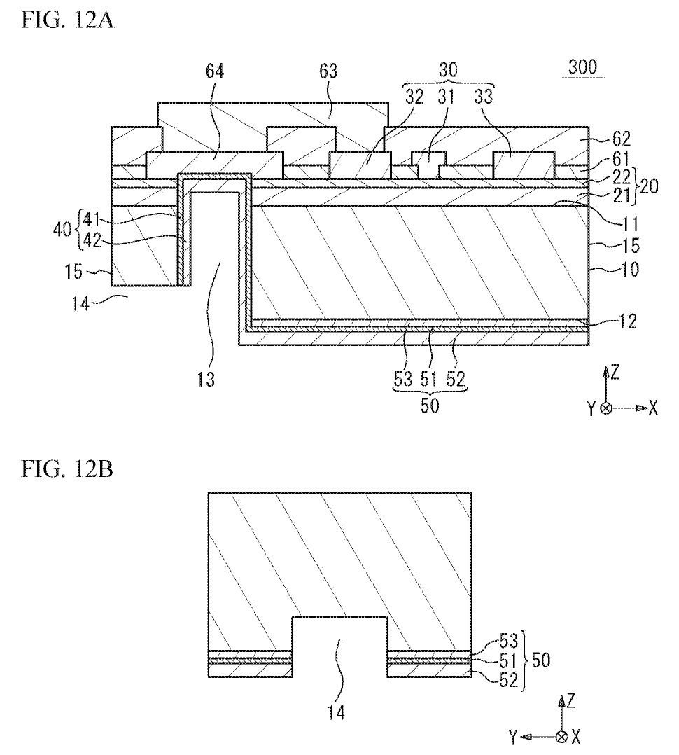

FIG. 12A is a cross-sectional view of a semiconductor device 300 according to a third embodiment, and FIG. 12B is a cross-sectional view of the groove 14 in the third embodiment. As illustrated in FIGS. 12A and 12B, in the third embodiment, all of the metal layer 55, the seed layer 56, and the plating layer 57 are not provided on the inner surface of the groove 14. Therefore, no metal layer is provided on the inner surface of the groove 14. The other configurations of the third embodiment are the same as those of the first embodiment, and thus the description thereof will be omitted.

### Manufacturing Method

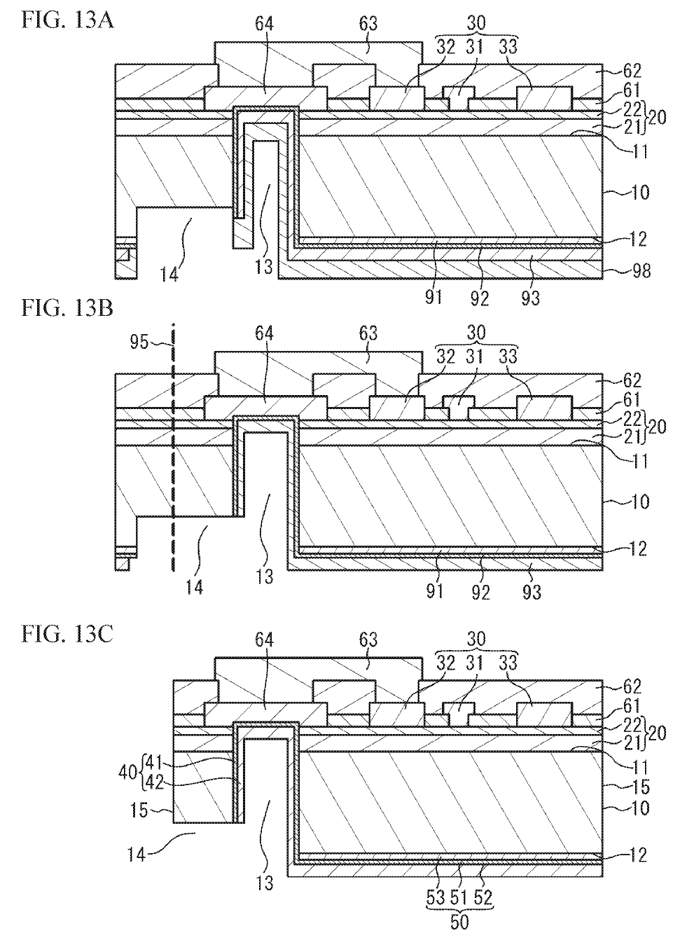

FIGS. 13A-13C are cross-sectional views illustrating a method of manufacturing the semiconductor device 300 according to the third embodiment. First, the steps illustrated in FIGS. 2A-3C of the first embodiment are performed, and then the steps illustrated in FIGS. 9A-9C of the second embodiment are performed. Next, as illustrated in FIG. 13A, the seed layer 92 and the metal mask layer 91 formed on the inner surface of the groove 14 are etched using the photoresist film 98 as a mask. The seed layer 92 and the metal mask layer 91 are etched by, for example, a wet etching method. As a result, the seed layer 92 and the metal mask layer 91 formed on the inner surface of the groove 14 are removed.

As illustrated in FIG. 13B, after the photoresist film 98 is removed, the semiconductor device is singulated along the dicing line 95.

As illustrated in FIG. 13C, the groove 14 connecting the through hole 13 and the side surface 15 of the substrate 10 is formed in the lower surface 12 of the substrate 10 by singulating the semiconductor device. The pad 50 including the metal layer 53 formed of the metal mask layer 91, the seed layer 51 formed of the seed layer 92, and the plating layer 52 formed of the plating layer 93 is formed on the lower surface 12 of the substrate 10. No metal layer is formed on the inner surface of the groove 14. The via wiring 40 including the seed layer 41 formed of the seed layer 92 and the plating layer 42 formed of the plating layer 93 is formed on the inner surface of the through hole 13. The via wiring 40 and the pad 50 are connected to each other. As described above, the semiconductor device 300 of the third embodiment is formed.

### Semiconductor Device in Third Embodiment

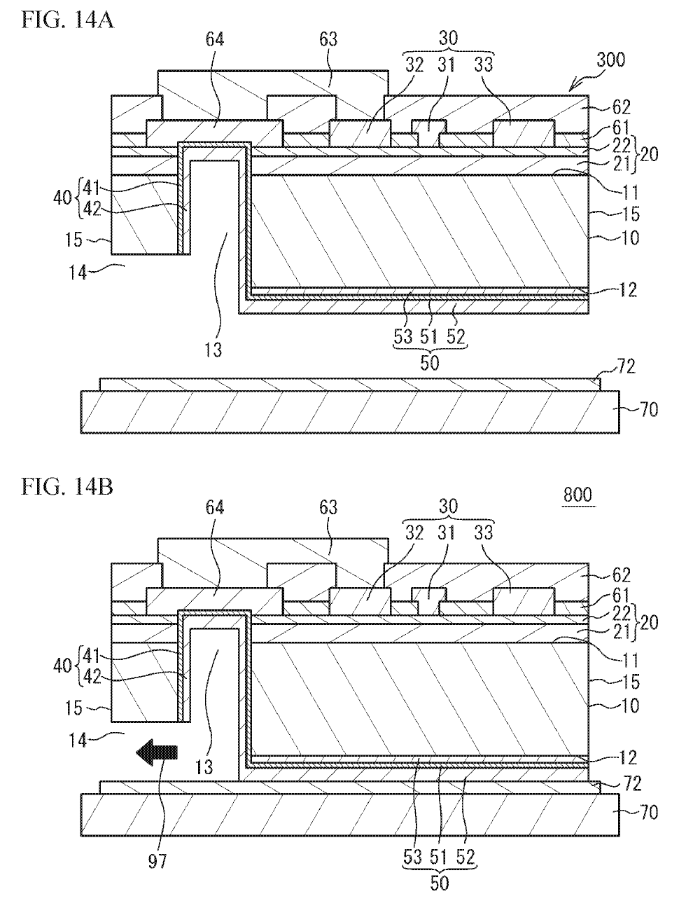

FIGS. 14A and 14B are cross-sectional views illustrating a step of mounting the semiconductor device 300 on the mounting substrate 70 to form a semiconductor apparatus 800 according to the third embodiment. As illustrated in FIGS. 14A and 14B, the pad 50 provided on the lower surface 12 of the substrate 10 is disposed on the solder material 72 provided on the mounting substrate 70, and the temperature of the solder material 72 is increased to an appropriate temperature, thereby bonding the pad 50 and the solder material 72. At this time, as in the first embodiment, since the groove 14 is provided in the lower surface 12 of the substrate 10 from the through hole 13 to the side surface 15 of the substrate 10, the air in the through hole 13 is discharged to the outside through the gap formed by the groove 14 as indicated by the arrow 97. Further, since no metal layer is provided on the inner surface of the groove 14, the solder material 72 is suppressed from entering the groove 14. That is, the gap between the substrate 10 and the mounting substrate 70 is suppressed from being blocked by the solder material 72. Therefore, a path for discharging the air in the through hole 13 to the outside can be more reliably secured, and the air in the through hole 13 can be more reliably discharged to the outside.

According to the third embodiment, as illustrated in FIGS. 12A and 12B, no metal layer is provided on the inner surface of the groove 14. This suppresses the solder material 72 from blocking the groove 14 and suppresses the air in the through hole 13 from being less likely to be discharged to the outside.

In the first to third embodiments, a case where the metal layer 64 is provided to cover the through hole 13 is described as an example, but the present disclosure is not limited to this case. The wiring 63 may directly cover the through hole 13 without providing the metal layer 64. In this case, the wiring 63 corresponds to the metal layer in the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A semiconductor device comprising:
a substrate having a first surface, a second surface, and a side surface connecting the first surface and the second surface;
a semiconductor element provided on the first surface;
a metal layer provided on the first surface and electrically connected to the semiconductor element;
a via wiring provided on an inner surface of a through hole and connected to the metal layer, the through hole penetrating from the first surface to the second surface and overlapping the metal layer in plan view; and
a pad provided on the second surface and connected to the via wiring,
wherein the substrate includes a groove provided in the second surface from the through hole to the side surface.

2. The semiconductor device according to claim 1,
wherein the pad includes a layer containing gold, and no layer containing gold is provided on an inner surface of the groove.

3. The semiconductor device according to claim 1,
wherein no metal layer is provided on an inner surface of the groove.

4. The semiconductor device according to claim 1,
wherein the groove is provided on a side opposite to the semiconductor element across the through hole.

5. The semiconductor device according to claim 1,
wherein a maximum width of the groove is smaller than a maximum width of the through hole in plan view.

6. The semiconductor device according to claim 1,
wherein a depth of the groove is 1/20 or more of a distance between the first surface and the second surface.

7. The semiconductor device according to claim 1,
wherein a depth of the groove is 1/4 or less of a distance between the first surface and the second surface.

8. The semiconductor device according to claim 1,
wherein the groove is provided linearly between the through hole and the side surface in plan view.

9. The semiconductor device according to claim 1,
wherein the semiconductor element includes a gate electrode, a source electrode, and a drain electrode, and the metal layer is electrically connected to the source electrode.

10. The semiconductor device according to claim 9, further comprising:
a channel layer provided on the first surface, the channel layer being a nitride semiconductor layer; and
an electron supply layer provided on the channel layer, the electron supply layer being a nitride semiconductor layer;
wherein the gate electrode, the source electrode, and the drain electrode are provided on the electron supply layer.

11. A semiconductor apparatus comprising:
a mounting substrate; and
a semiconductor device mounted on the mounting substrate with a solder material,
wherein the semiconductor device includes:
a substrate having a first surface, a second surface, and a side surface connecting the first surface and the second surface;
a semiconductor element provided on the first surface;
a metal layer provided on the first surface and electrically connected to the semiconductor element;
a via wiring provided on an inner surface of a through hole and connected to the metal layer, the through hole penetrating from the first surface to the second surface and overlapping the metal layer in plan view; and
a pad provided on the second surface, connected to the via wiring, and bonded to the solder material, and
wherein the substrate includes a groove provided in the second surface from the through hole to the side surface.

12. The semiconductor apparatus according to claim 11,
wherein the pad includes a layer containing gold, the solder material is a solder material containing gold, and no layer containing gold is provided on an inner surface of the groove.

13. The semiconductor apparatus according to claim 11,
wherein no metal layer is provided on an inner surface of the groove.

14. The semiconductor apparatus according to claim 12,
wherein the solder material is gold-tin solder.
